(19) United States
(12) Patent Application Publication
(10) Pub. No.: US 2015/0021527 A1
(43) Pub. Date: Jan. 22, 2015

(54) COMPOSITION FOR SOLAR CELL ELECTRODES AND ELECTRODE FABRICATED USING THE SAME

(71) Applicants: Dong Il SHIN, Uiwang-si (KR); Kuninori OKAMOTO, Uiwang-si (KR); Hee In NAM, Uiwang-si (KR)

(72) Inventors: Dong Il SHIN, Uiwang-si (KR); Kuninori OKAMOTO, Uiwang-si (KR); Hee In NAM, Uiwang-si (KR)

(21) Appl. No.: 14/258,637

(22) Filed: Apr. 22, 2014

(30) Foreign Application Priority Data
Jul. 19, 2013 (KR) 10-2013-0085672

(51) Int. Cl. H01L 31/0224

(52) U.S. Cl. CPC H01L 31/022425
USPC 252/514

(57) ABSTRACT

A composition for solar cell electrodes includes a conductive powder, a glass frit, an organic vehicle, and a thermosetting resin, the thermosetting resin being present in an amount of about 0.5 wt % to about 30 wt % based on a total weight of the composition.

### CROSS-REFERENCE TO RELATED APPLICATION

The present application claims priority under 35 U.S.C. §119 to Korean Patent Application No. 10-2013-0085672, filed on Jul. 19, 2013, in the Korean Intellectual Property Office, and entitled: “Composition for Solar Cell Electrodes and Electrode Fabricated Using the Same,” which is incorporated by reference herein in its entirety.

1. Field

Embodiments relate to a composition for solar cell electrodes and electrodes fabricated using the same.

2. Description of the Related Art

Solar cells generate electricity using the photovoltaic effect of a p-n junction which converts photons of sunlight into electricity. In the solar cell, front and rear electrodes are formed on upper and lower surfaces of a semiconductor wafer or substrate with the p-n junctions, respectively. Then, the photovoltaic effect at the p-n junction is induced by sunlight entering the semiconductor wafer and electrons generated by the photovoltaic effect at the p-n junction provide electric current to the outside through the electrodes.

### SUMMARY

Embodiments are directed to a composition for solar cell electrodes, the composition including: a conductive powder, a glass frit, an organic vehicle, and a thermosetting resin, the thermosetting resin being present in an amount of about 0.5 wt % to about 30 wt % based on a total weight of the composition.

The composition may include about 60 wt % to about 95 wt % of the conductive powder, about 0.5 wt % to about 20 wt % of the glass fit, about 1 wt % to about 30 wt % of the organic vehicle, and about 0.5 wt % to about 30 wt % of the thermosetting resin.

The composition may further include: about 0.1 wt % to about 1 wt % of a curing agent, and about 0.1 wt % to about 5 wt % of a reducing agent.

The thermosetting resin may include one or more of a bisphenol A epoxy resin, a tetra-functional epoxy resin, a tri-functional epoxy resin, an isocyanate resin, or a bismaleimide resin.

The curing agent may include one or more of m-phenylene diamine (MPDA), diamino diphenyl methane (DDM), diamino diphenyl sulfone (DDS), methyl nadic anhydride (MNA), dodecenyl succinic anhydride (DDSA), maleic anhydride (MA), succinic anhydride (SA), methyltetrahydrophthalic anhydride (MTHPA), hexahydrophthalic anhydride (HHPA), tetrahydrophthalic anhydride (THPA), or pyromellitic dianhydride (PMDA).

The reducing agent may include one or more of glutaric acid, malic acid, azelaic acid, abietic acid, adipic acid, ascorbic acid, acrylic acid, or citric acid.

The conductive powder may be a silver powder having an average particle diameter (D50) of about 0.1 μm to about 10 μm.

The glass frit may include one or more of zinc oxide-silicon oxide (ZnO—SiO₂) glass fit, zinc oxide-boron oxide-silicon oxide (ZnO—B₂O₃—SiO₂) glass frit, zinc oxide-boron oxide-silicon oxide-aluminum oxide (ZnO—B₂O₃—SiO₂—Al₂O₃) glass frit, bismuth oxide (Bi₂O₃) glass frit, bismuth oxide-silicon oxide (Bi₂O₃—SiO₂) glass fit, bismuth oxide-boron oxide-silicon oxide (Bi₂O₃—B₂O₃—SiO₂) glass fit, bismuth oxide-boron oxide-silicon oxide-aluminum oxide (Bi₂O₃—B₂O₃—SiO₂—Al₂O₃) glass frit, bismuth oxide-zinc oxide-boron oxide-silicon oxide (Bi₂O₃—ZnO—B₂O₃—SiO₂) glass frit, bismuth oxide-zinc oxide-boron oxide-silicon oxide-aluminum oxide (Bi₂O₃—ZnO—B₂O₃—SiO₂—Al₂O₃) glass frit, lead oxide (PbO) glass frit, lead oxide-tellurium oxide (PbO—TeO₂) glass frit, lead oxide-tellurium oxide-silicon oxide (PbO—TeO₂—SiO₂) glass frit, lead oxide-tellurium oxide-lithium oxide (PbO—TeO₂—Li₂O) glass frit, bismuth oxide-tellurium oxide (Bi₂O₃—TeO₂) glass fit, bismuth oxide-tellurium oxide-silicon oxide (Bi₂O₃—TeO₂—SiO₂) glass frit, bismuth oxide-tellurium oxide-lithium oxide (Bi₂O₃—TeO₂—Li₂O) glass frit, tellurium oxide (TeO₂) glass frit, or tellurium oxide-zinc oxide (TeO₂—ZnO) glass frit.

The glass frit may have an average particle diameter (D50) of about 0.1 μm to about 10 μm.

The composition may further include one or more of a dispersant, a thixotropic agent, a plasticizer, a viscosity stabilizer, an anti-foaming agent, a pigment, a UV stabilizer, an antioxidant, or a coupling agent.

Embodiments are also directed to a solar cell electrode prepared from a composition according to an embodiment.

Embodiments are also directed to a solar cell including an electrode according to an embodiment.

### BRIEF DESCRIPTION OF THE DRAWINGS

Features will become apparent to those of skill in the art by describing in detail exemplary embodiments with reference to the attached drawings in which:

FIG. 1 illustrates a photomicrograph (a) of an electrode fabricated using a composition for solar cell electrodes in Example 1 and a sectional view (b) of the electrode.

FIG. 2 illustrates a photomicrograph (a) of an electrode fabricated using a composition for solar cell electrodes in Comparative Example 1 and a sectional view (b) of the electrode.

FIG. 3 illustrates a schematic view of a solar cell in accordance with an example embodiment.

FIG. 4 illustrates Table 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. Like reference numerals refer to like elements throughout.

Composition for Solar Cell Electrodes

A composition for solar cell electrodes according to an example embodiment includes a conductive powder; a glass frit; an organic vehicle; and a thermosetting resin. The thermosetting resin may be present in an amount of, e.g., about 0.5 wt % to about 30 wt % based on a total weight of the composition.

Hereinafter, components of the composition for solar cell electrodes according to an example embodiment will be described in more detail.

Conductive Powder

The conductive powder may include one or more of silver (Ag), gold (Au), palladium (Pd), platinum (Pt), copper (Cu), aluminum (Al), nickel (Ni), or indium tin oxide (ITO) powder, etc. In an implementation, the conductive powder may include silver powder or mixtures including silver powder.

The conductive powder may have a nanometer or micrometer-scale particle size. For example, the conductive powder may have a particle size of dozens to several hundred nanometers, or a particle diameter of several to dozens of micrometers. In an implementation, the conductive powder may be a mixture of two or more types of conductive powders having different particle sizes.

The conductive powder may have a spherical, flake, or amorphous particle shape.

The conductive powder may have an average particle diameter (D50) of about 0.1 μm to about 10 μm, e.g., about 0.5 μm to about 5 μm. The average particle diameter may be measured using, for example, a Model 1064D (CILAS Co., Ltd.) after dispersing the conductive powder in isopropyl alcohol (IPA) at 25° C. for 3 minutes via ultrasonication. Within this range of average particle diameter, the composition may provide low contact resistance (Rc) and low line resistance.

The silver powder may be present in an amount of, e.g., about 60 wt % to about 95 wt % based on the total weight of the composition. Within this range, the conductive powder may help prevent deterioration in conversion efficiency caused by an increase in resistance. In an implementation, the conductive powder may be present in an amount of, e.g., about 70 wt % to about 90 wt %.

(B) Glass Frit

The glass fit may be used to enhance adhesion between the conductive powder and the wafer or the substrate, and to form silver crystal grains in an emitter region by etching an anti-reflection layer and melting the silver powder so as to reduce contact resistance (Rc) during the baking process of the composition for electrodes. Further, during the baking process, the glass frit may soften and decrease the baking temperature.

When the area of the solar cell is increased in order to improve solar cell efficiency, there may be a problem of increase in solar cell contact resistance (Rc). Thus, it is desirable to minimize both serial resistance (Rs) and an influence on the p-n junction. In addition, as the baking temperatures may vary within a broad range with increasing use of various wafers having different sheet resistances, it is desirable that the glass frit provide sufficient thermal stability to withstand a wide range of baking temperatures.

The glass frit may include one or more of a leaded glass frit or a lead-free glass fit for a composition for a solar cell electrode.

In an example embodiment, the glass frit may include lead oxide, silicon oxide, tellurium oxide, bismuth oxide, zinc oxide, boron oxide, aluminum oxide, tungsten oxide, or combinations thereof. For example, the glass frit may include one or more of zinc oxide-silicon oxide (ZnO—SiO₂) glass frit, zinc oxide-boron oxide-silicon oxide (ZnO—B₂O₃—SiO₂) glass fit, zinc oxide-boron oxide-silicon oxide-aluminum oxide (ZnO—B₂O₃—SiO₂—Al₂O₃) glass frit, bismuth oxide (Bi₂O₃) glass frit, bismuth oxide-silicon oxide (Bi₂O₃—SiO₂) glass frit, bismuth oxide-boron oxide-silicon oxide (Bi₂O₃—B₂O₃—SiO₂) glass frit, bismuth oxide-boron oxide-silicon oxide-aluminum oxide (Bi₂O₃—B₂O₃—SiO₂—Al₂O₃) glass fit, bismuth oxide-zinc oxide-boron oxide-silicon oxide (Bi₂O₃—ZnO-B₂O₃—SiO₂) glass fit, bismuth oxide-zinc oxide-boron oxide-silicon oxide-aluminum oxide (Bi₂O₃—ZnO—B₂O₃—SiO₂—Al₂O₃) glass fit, lead oxide (PbO) glass frit, lead oxide-tellurium oxide (PbO—TeO₂) glass frit, lead oxide-tellurium oxide-silicon oxide (PbO—TeO₂—SiO₂) glass frit, lead oxide-tellurium oxide-lithium oxide (PbO—TeO₂—Li₂O) glass frit, bismuth oxide-tellurium oxide (Bi₂O₃—TeO₂) glass frit, bismuth oxide-tellurium oxide-silicon oxide (Bi₂O₃—TeO₂—SiO₂) glass frit, bismuth oxide-tellurium oxide-lithium oxide (Bi₂O₃—TeO₂—Li₂O) glass frit, tellurium oxide (TeO₂) glass frit, tellurium oxide-zinc oxide (TeO₂—ZnO) glass frit, etc.

The glass frit may have an average particle diameter D50 of about 0.1 μm to about 10 μm, and may be present in an amount of, e.g., about 0.5 wt % to about 20 wt % based on a total weight of the composition. The glass frit may have a spherical or amorphous shape. In an example embodiment, a mixture of two types of glass frits having different glass transition points may be used for the composition. For example, a mixture of a first glass fit having a glass transition point ranging from 200° C. to 350° C. and a second glass fit having a glass transition point of more than 350° C. and less than or equal to 550° C. may be used, and the weight ratio of the first glass fit to the second glass fit may range from about 1:0.2 to about 1:1.

The glass frit may be prepared from such metal oxides by general method. The metal oxides may be mixed in a predetermined ratio. Mixing may be carried out using, e.g., a ball mill or a planetary mill. The mixture may be melted at 700° C. to 1300° C., followed by quenching to 25° C. The obtained resultant may be subjected to pulverization using a disk mill, a planetary mill, or the like, thereby preparing a glass frit.

(C) Organic Vehicle

The organic vehicle may be used to impart suitable viscosity and rheological characteristics for printing to the composition for solar cell electrodes through mechanical mixing with the inorganic component of the composition.

The organic vehicle may be a general organic vehicle for a solar cell electrode composition, and may include a binder resin, a solvent, or the like.

The binder resin may include one or more of an acrylate resin, a cellulose resin, etc. Ethyl cellulose may be used as the binder resin. In addition, the binder resin may include one or more of ethyl hydroxyethyl cellulose, nitrocellulose, a blend of ethyl cellulose and phenol resins, an alkyd resin, a phenol resin, an acrylic ester resin, a xylenic resin, a polybutene resin, a polyester resin, a urea resin, a melamine resin, a vinyl acetate resin, a wood rosin, a polymethacrylate of alcohol, etc.

Examples of the solvent may include one or more of hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, texanol, methylethylketone, benzylalcohol, γ-butyrolactone, ethyl lactate, etc. These solvents may be used alone or in combinations thereof.

The organic vehicle may be present in an amount of, e.g., about 1 wt % to about 30 wt % based on a total weight of the composition. Within this range, the organic vehicle may help provide sufficient adhesive strength and excellent printability to the composition.

(D) Thermosetting Resin

The thermosetting resin may be used to help obtain fine patterns in printing with the composition, and to form electrodes having a high aspect ratio (thickness/linewidth of electrodes).

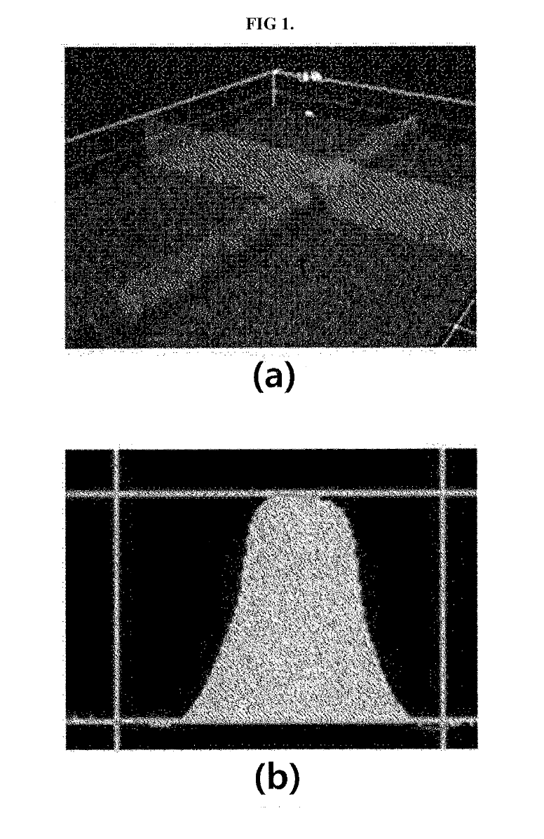

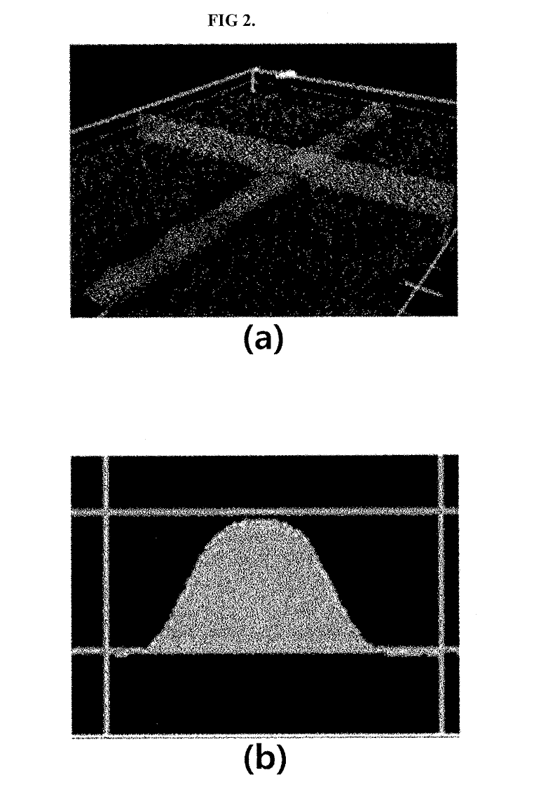

FIG. 1 shows a photomicrograph (a) of an electrode fabricated using a composition for solar cell electrodes including a thermosetting resin according to an example embodiment, and a sectional view (b) of the electrode. FIG. 2 shows a photomicrograph (a) of an electrode fabricated using a comparative composition for solar cell electrodes not including the thermosetting resin, and a sectional view (b) of the electrode. Referring to FIGS. 1 to 2, it can be seen that the electrode including the thermosetting resin has a higher aspect ratio than the electrode not including the thermosetting resin.

The thermosetting resin may include one or more of a bisphenol A epoxy resin, a tetra-functional epoxy resin, a tri-functional epoxy resin, an isocyanate resin, a bismaleimide resin, etc. These may be used alone or in combination thereof.

The thermosetting resin may be present in an amount of, e.g., about 0.5 wt % to about 30 wt %, e.g., about 1 wt % to about 20 wt %, based on a total weight of the composition. Within this range, during drying after electrode pattern printing, initial shrinkage in linewidth of electrodes may occur to form fine linewidths, and residues on the printed wafer may be minimized upon shrinkage, which may help prevent a decrease in short circuit current (Isc).

(E) Curing Agent

The curing agent may include, e.g., one or more of an amine curing agent or an anhydride curing agent.

The amine curing agent may include one or more of m-phenylene diamine (MPDA), diamino diphenyl methane (DDM), diamino diphenyl sulfone (DDS), or the like, without being limited thereto. These may be used alone or as mixtures thereof. The anhydride curing agents may include methyl nadic anhydride (MNA), dodecenyl succinic anhydride (DDSA), maleic anhydride (MA), succinic anhydride (SA), methyltetrahydrophthalic anhydride (MTHPA), hexahydrophthalic anhydride (HHPA), tetrahydrophthalic anhydride (THPA), pyromellitic dianhydride (PMDA), etc. These may be used alone or as mixtures thereof.

The curing agent may be present in an amount of, e.g., about 0.1 wt % to about 1 wt % based on a total weight of the composition. Within this range, after pattern-printing and drying, a predetermined dried pattern may be obtained.

(F) Reducing Agent

The reducing agent may include one or more of glutaric acid, malic acid, azelaic acid, abietic acid, adipic acid, ascorbic acid, acrylic acid, citric acid, etc. These may be used alone or as mixture thereof.

The reducing agent may be present in an amount of, e.g., about 0.1 wt % to about 5 wt % based on the total weight of the composition. Within this range, after pattern-printing, excellent drying shrinkage property may be obtained.

(G) Additives

The composition may further include an additive, e.g., to enhance flow and process properties and stability. The additive may include one or more of a dispersant, a thixotropic agent, a plasticizer, a viscosity stabilizer, an anti-foaming agent, a pigment, a UV stabilizer, an antioxidant, a coupling agent, etc. The additives may be used alone or as mixtures thereof. The additives may be present in the composition in an amount of, e.g., about 0.1 wt % to about 5 wt %.

Solar Cell Electrode and Solar Cell Including the Same

Example embodiments relate to an electrode formed of the composition for solar cell electrodes according to an embodiment and a solar cell including the electrode.

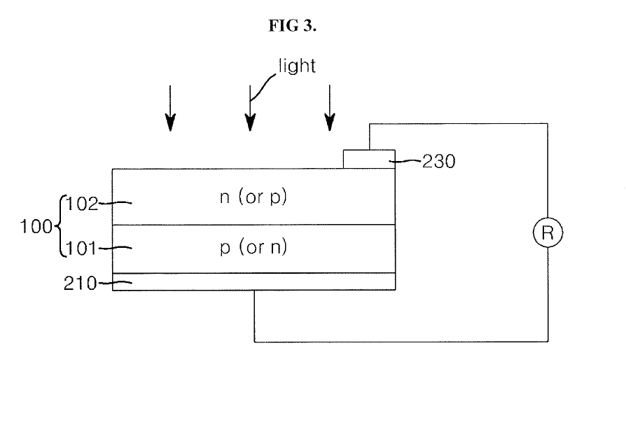

FIG. 3 shows a solar cell in accordance with an example embodiment.

Referring to FIG. 3, a rear electrode 210 and a front electrode 230 may be formed by printing and baking the composition on a wafer or substrate 100 that includes a p-layer (or n-layer) 101 and an n-layer (or p-layer) 102, which will serve as an emitter. For example, a preliminary process of preparing the rear electrode 210 may be performed by printing the composition on the rear surface of the wafer 100 and drying the printed composition at about 200° C. to about 400° C. for about 10 seconds to 60 seconds. Further, a preliminary process for preparing the front electrode may be performed by printing the paste on the front surface of the wafer and drying the printed composition. Then, the front electrode 230 and the rear electrode 210 may be formed by baking the wafer at about 400° C. to about 950° C., e.g., at about 750° C. to about 950° C., for about 30 seconds to 180 seconds.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Example 1

As an organic binder, 0.2 wt % of ethylcellulose (STD4, Dow Chemical Company) was sufficiently dissolved in 0.8 wt % of butyl carbitol at 60° C., and 87 wt % of spherical silver powder (AG-4-8, Dowa Hightech Co., Ltd.) having an average particle diameter of 2.0 μm, 4.0 wt % of a low melting point leaded glass frit (leaded glass, CI-124, Particlogy Co., Ltd.) having an average particle diameter of 1.0 μm and a transition point of 341° C., 6.3 wt % of a thermosetting resin (YD136, Kukdo Chemical Co., Ltd.), 0.7 wt % of a curing agent (KH620, Kukdo Chemical Co., Ltd.), 0.5 wt % of a reducing agent (Meta Phenylene Diamine, Aldrich Chemical Co.), 0.2 wt % of a dispersant BYK102 (BYK-Chemie, BYK Co., Ltd.), and 0.3 wt % of a thixotropic agent Thixatrol ST (Elementis Co., Ltd.) were added to the binder solution, followed by mixing and kneading in a 3-roll kneader, thereby preparing a composition for solar cell electrodes.

The compositions prepared in the Examples were deposited over a front surface of a poly p-type silicon wafer having a sheet resistance of 90 Ω by screen printing using Screen Masks 1 and 2 (described below) to print electrode patterns (finger bars), followed by drying in an IR drying furnace. Then, a composition for electrodes containing aluminum was printed on a rear side of the wafer and dried in the same manner as above. Cells formed according to this procedure were subjected to baking at 400° C. to 950° C. for 30 seconds to 180 seconds in a belt-type baking furnace, and evaluated as to fill factor (FF, %), conversion efficiency (%), short circuit current (Isc), open voltage (Voc), and serial resistance (Rs) using a solar cell efficiency tester CT-801 (Pasan Co., Ltd.). In order to confirm disconnection of the prepared electrodes (finger bars), the number of line opens was measured using an EL tester (MV Tech Inc.). The linewidth and thickness of electrode lines were measured using VK equipment (VK9710, KEYENCE Co., Ltd.).

Screen Mask 1: SUS325 type; emulsion thickness: 15 μm; linewidth of finger bars: 45 μm; number of finger bars: 80

Screen Mask 2: SUS325 type; emulsion thickness: 15 μm; linewidth of finger bars: 35 μm; number of finger bars: 90)

### Examples 2 to 5 and Comparative Examples 1 to 2

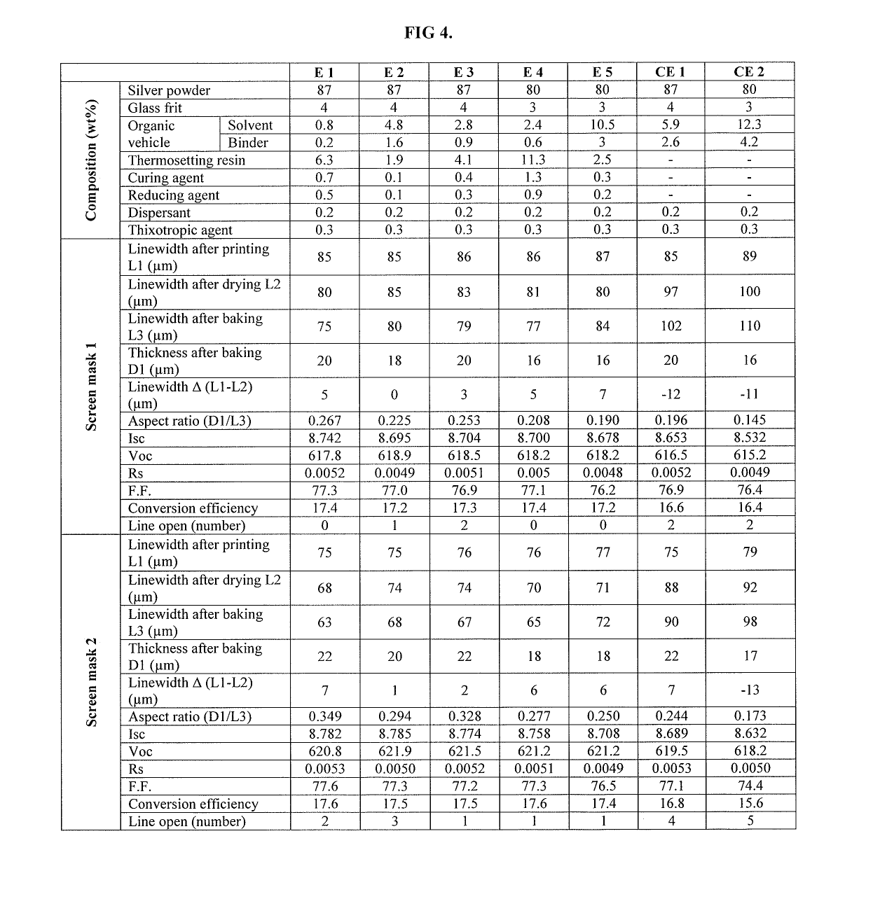

Solar cell electrodes were prepared in the same manner as in Example 1 except that the compositions were prepared in amounts as listed in Table 1 in FIG. 4. Results are also shown in Table 1 in FIG. 4.

Referring to Table 1, solar cell electrodes fabricated using the compositions containing the thermosetting resin in Examples 1 to 5 provided fine linewidths through initial shrinkage in linewidth of electrodes a during drying process after electrode pattern-printing, and minimized formation of residues on the printed surface of the wafer upon shrinkage, and provided high short circuit current and excellent conversion efficiency, as compared with Comparative Example 1 to 2.

By way of summation and review, an electrode of a solar cell may be formed on a wafer by applying, patterning, and baking an electrode composition. A composition for solar cell electrodes that has enhanced contact efficiency with respect to a wafer to minimize contact resistance (Rc) and serial resistance (Rs), or that uses organic materials to increase short circuit current (Isc) by decreasing a linewidth of a screen mask pattern to form fine linewidths, may be used in an effort to improve conversion efficiency of solar cell electrodes. However, decrease in linewidth of electrodes using the screen mask may cause problems of increase in serial resistance (Rs) and deterioration in continuous printability of fine patterns.

As described above, embodiments may provide a composition for solar cell electrodes, which may be used to fabricate electrodes having fine linewidths and high aspect ratio, and solar cell electrodes fabricated using the same, which may have a high short circuit current (Isc) and exhibit excellent fill factor and conversion efficiency.

Example embodiments have been disclosed herein, and although specific teams are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A composition for solar cell electrodes, the composition comprising: a conductive powder; a glass frit; an organic vehicle; and a thermosetting resin, the thermosetting resin being present in an amount of about 0.5 wt % to about 30 wt % based on a total weight of the composition.

2. The composition as claimed in claim 1, comprising: about 60 wt % to about 95 wt % of the conductive powder; about 0.5 wt % to about 20 wt % of the glass frit; about 1 wt % to about 30 wt % of the organic vehicle; and about 0.5 wt % to about 30 wt % of the thermosetting resin.

3. The composition as claimed in claim 1, further comprising: about 0.1 wt % to about 1 wt % of a curing agent; and about 0.1 wt % to about 5 wt % of a reducing agent.

4. The composition as claimed in claim 1, wherein the thermosetting resin includes one or more of a bisphenol A epoxy resin, a tetra-functional epoxy resin, a tri-functional epoxy resin, an isocyanate resin, or a bismaleimide resin.

5. The composition as claimed in claim 3, wherein the curing agent includes one or more of m-phenylene diamine (MPDA), diamino diphenyl methane (DDM), diamino diphenyl sulfone (DDS), methyl nadic anhydride (MNA), dodecenyl succinic anhydride (DDSA), maleic anhydride (MA), succinic anhydride (SA), methyltetrahydrophthalic anhydride (MTHPA), hexahydrophthalic anhydride (HHPA), tetrahydrophthalic anhydride (THPA), or pyromellitic dianhydride (PMDA).

6. The composition as claimed in claim 3, wherein the reducing agent includes one or more of glutaric acid, malic acid, azelaic acid, abietic acid, adipic acid, ascorbic acid, acrylic acid, or citric acid.

7. The composition as claimed in claim 1, wherein the conductive powder is a silver powder having an average particle diameter (D50) of about 0.1 μm to about 10 μm.

8. The composition as claimed in claim 1, wherein the glass frit includes one or more of zinc oxide-silicon oxide (ZnO—SiO₂) glass fit, zinc oxide-boron oxide-silicon oxide (ZnO—B₂O₃—SiO₂) glass frit, zinc oxide-boron oxide-silicon oxide-aluminum oxide (ZnO—B₂O₃—SiO₂—Al₂O₃) glass frit, bismuth oxide (Bi₂O₃) glass frit, bismuth oxide-silicon oxide (Bi₂O₃—SiO₂) glass frit, bismuth oxide-boron oxide-silicon oxide (Bi₂O₃—B₂O₃—SiO₂) glass frit, bismuth oxide-boron oxide-silicon oxide-aluminum oxide (Bi₂O₃—B₂O₃—SiO₂—Al₂O₃) glass frit, bismuth oxide-zinc oxide-boron oxide-silicon oxide (Bi₂O₃—ZnO—B₂O₃—SiO₂) glass frit, bismuth oxide-zinc oxide-boron oxide-silicon oxide-aluminum oxide (Bi₂O₃—ZnO—B₂O₃—SiO₂—Al₂O₃) glass frit, lead oxide (PbO) glass frit, lead oxide-tellurium oxide (PbO—TeO₂) glass frit, lead oxide-tellurium oxide-silicon oxide (PbO—TeO₂—SiO₂) glass frit, lead oxide-tellurium oxide-lithium oxide (PbO—TeO₂—Li₂O) glass frit, bismuth oxide-tellurium oxide (Bi₂O₃—TeO₂) glass frit, bismuth oxide-tellurium oxide-silicon oxide (Bi₂O₃—TeO₂—SiO₂) glass frit, bismuth oxide-tellurium oxide-lithium oxide (Bi₂O₃—TeO₂—Li₂O) glass frit, tellurium oxide (TeO₂) glass frit, or tellurium oxide-zinc oxide (TeO₂—ZnO) glass frit.

9. The composition as claimed in claim 1, wherein the glass frit has an average particle diameter (D50) of about 0.1 μm to about 10 μm.

10. The composition as claimed in claim 1, further comprising: one or more of a dispersant, a thixotropic agent, a plasticizer, a viscosity stabilizer, an anti-foaming agent, a pigment, a UV stabilizer, an antioxidant, or a coupling agent.

11. A solar cell electrode prepared from the composition as claimed in claim 1.

12. A solar cell comprising the electrode as claimed in claim 11.
